(19) United States
(12) Patent Application Publication
(10) Pub. No.: US 2024/0105680 A1
(43) Pub. Date: Mar. 28, 2024

(54) SEMICONDUCTOR CHIP STACK STRUCTURE AND SEMICONDUCTOR PACKAGE INCLUDING THE SAME

(71) Applicant: SAMSUNG ELECTRONICS CO., LTD., Suwon-si (KR)

(72) Inventors: Junyoung Oh, Suwon-si (KR); Jumyong Park, Suwon-si (KR); Dongjoon Oh, Suwon-si (KR)

(73) Assignee: SAMSUNG ELECTRONICS CO., LTD., Suwon-si (KR)

(21) Appl. No.: 18/198,418

(22) Filed: May 17, 2023

(30) Foreign Application Priority Data
Sep. 23, 2022 (KR) 10-2022-0120591

(51) Int. Cl. H01L 25/065; H01L 23/00; H01L 23/31; H01L 23/498

(52) U.S. Cl. CPC H01L 25/0657; H01L 23/3107; H01L 23/49827; H01L 24/08; H01L 24/16; H01L 24/48; H01L 24/73; H01L 2224/08146; H01L 2224/16225; H01L 2224/48147; H01L 2224/48149; H01L 2224/73257; H01L 2225/06506; H01L 2225/06517; H01L 2225/06541; H01L 2924/15321

(57) ABSTRACT

A semiconductor chip stack structure includes: a first semiconductor chip including a first semiconductor substrate, a first redistribution layer on the first semiconductor substrate and including a first redistribution pattern, and a first pad on an outermost side of the first redistribution layer; a second semiconductor chip including a second semiconductor substrate, a second redistribution layer on the second semiconductor substrate and including a second redistribution pattern, and a second pad on an outermost side of the second redistribution layer, and an area of the second semiconductor chip being smaller than an area of the first semiconductor chip; a first metal wire on the first semiconductor chip; a second metal wire on the second semiconductor chip; and a molding member on the first semiconductor chip and at least a portion of each of the second semiconductor chip, the first metal wire, and the second metal wire.

### CROSS-REFERENCE TO RELATED APPLICATION

This application claims priority to Korean Patent Application No. 10-2022-0120591, filed on Sep. 23, 2022 in the Korean Intellectual Property Office, the disclosure of which is incorporated by reference herein in its entirety.

### BACKGROUND

The disclosure relates to a semiconductor chip stack structure and a semiconductor package including the same.

Over the preceding decades, computing power and wireless communications technology have advanced rapidly due to the development of technology, materials and manufacturing processes. Accordingly, high-performance transistors have been realized, and a rate of integration has rapidly increased according to Moore's Law. Thinning and miniaturization of systems and improvements of power efficiency are generally goals of the semiconductor manufacturing industry, and at the present time, when economic and physical process limits have been reached, a semiconductor chip stack structure in which a plurality of semiconductor chips are stacked and a semiconductor package including the same may be an effective solution.

### SUMMARY

One or more example embodiments provide a semiconductor chip stack structure capable of die-to-wafer bonding and and that may solve various problems in a chemical mechanical polishing (CMP) process.

One or more example embodiments provide a semiconductor package including a semiconductor chip stack structure capable of die-to-wafer bonding and solving various problems in a CMP process.

According to an aspect of an example embodiment, a semiconductor chip stack structure includes: a first semiconductor chip comprising a first semiconductor substrate, a first redistribution layer on the first semiconductor substrate and comprising a first redistribution pattern, and a first pad on an outermost side of the first redistribution layer; a second semiconductor chip comprising a second semiconductor substrate, a second redistribution layer on the second semiconductor substrate and comprising a second redistribution pattern, and a second pad on an outermost side of the second redistribution layer, the second semiconductor chip being stacked on the first semiconductor chip such that the first pad and the second pad are bonded to each other with the first redistribution layer and the second redistribution layer facing each other, and an area of the second semiconductor chip being smaller than an area of the first semiconductor chip; a first metal wire on the first semiconductor chip; a second metal wire on the second semiconductor chip; and a molding member on the first semiconductor chip and at least a portion of each of the second semiconductor chip, the first metal wire, and the second metal wire, wherein an upper surface of each of the first metal wire and the second metal wire is exposed from an upper surface of the molding member.

According to an aspect of an example embodiment, a semiconductor chip stack structure includes: a first semiconductor chip comprising a first semiconductor substrate, a first redistribution layer on the first semiconductor substrate and comprising a first redistribution pattern, and a first pad on an outermost side of the first redistribution layer; a second semiconductor chip comprising a second semiconductor substrate, a second redistribution layer on the second semiconductor substrate and comprising a second redistribution pattern, and a second pad on an outermost side of the second redistribution layer, the second semiconductor chip being stacked on the first semiconductor chip such that the first pad is bonded to the second pad and the first redistribution layer faces the second redistribution layer, and an area of the second semiconductor chip being smaller than an area of the first semiconductor chip; a first metal wire on the first semiconductor chip; and a molding member on the first semiconductor chip and at least a portion of each of the second semiconductor chip and the first metal wire.

According to an aspect of an example embodiment, a semiconductor package includes: a printed circuit board (PCB); and a semiconductor chip stack structure on the PCB, wherein the semiconductor chip stack structure comprises: a first semiconductor chip comprising a first semiconductor substrate, a first redistribution layer disposed on the first semiconductor substrate and comprising a first redistribution pattern, and a first pad on an outermost side of the first redistribution layer; a second semiconductor chip including a second semiconductor substrate, a second redistribution layer on the second semiconductor substrate and comprising a second redistribution pattern, and a second pad on an outermost side of the second redistribution layer, the second semiconductor chip stacked on the first semiconductor chip such that the first pad is bonded to the second pad with the first redistribution layer facing the second redistribution layer, and an area of the second semiconductor chip being smaller than an area of the first semiconductor chip; a first metal wire on the first semiconductor chip; and a molding member on the first semiconductor chip and at least a portion of each of the second semiconductor chip and the first metal wire.

### BRIEF DESCRIPTION OF DRAWINGS

The above and other aspects and features will be more apparent from the following description of example embodiments, taken in conjunction with the accompanying drawings, in which:

FIG. 1 is a schematic cross-sectional view of a semiconductor chip stack structure according to example embodiments;

FIG. 2 is a schematic top view of a semiconductor chip stack structure according to the example embodiments illustrated in FIG. 1;

FIGS. 3 to 7 are cross-sectional views illustrating sequential processes of a method of manufacturing the semiconductor chip stack structure according to the example embodiments illustrated in FIG. 1;

FIG. 8 is a schematic cross-sectional view of a semiconductor package according to example embodiments;

FIG. 9 is a schematic cross-sectional view of a semiconductor chip stack structure according to example embodiments;

FIGS. 10 through 15 are cross-sectional views illustrating sequential processes of a method of manufacturing a semiconductor chip stack structure according to the example embodiment illustrated in FIG. 9;

FIG. 16 is a schematic cross-sectional view of a semiconductor package according to example embodiments;

FIG. 17 is a schematic cross-sectional view of a semiconductor chip stack structure according to example embodiments;

FIGS. 18 to 22 are cross-sectional views illustrating sequential processes of a method of manufacturing a semiconductor chip stack structure according to the example embodiments illustrated in FIG. 17; and

FIG. 23 is a schematic cross-sectional view of a semiconductor package according to example embodiments.

### DETAILED DESCRIPTION

Example embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

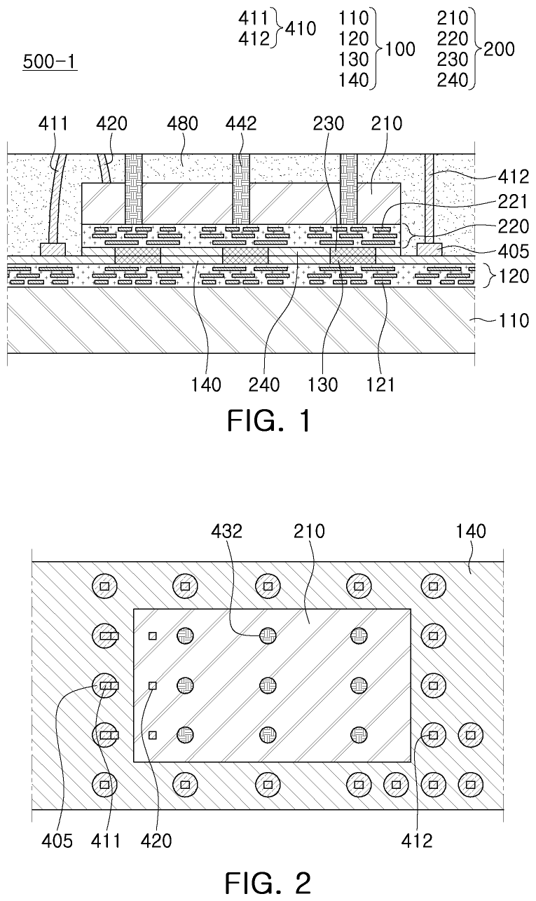

FIG. 1 is a schematic cross-sectional view of a semiconductor chip stack structure according to example embodiments, and FIG. 2 is a schematic top view of the semiconductor chip stack structure according to example embodiments illustrated in FIG. 1. In FIG. 2, the molding member is omitted for convenience.

Referring to FIGS. 1 and 2, a semiconductor chip stack structure 500-1 may include a first semiconductor chip 100 including a first semiconductor substrate 110, a first redistribution layer 120 disposed on the first semiconductor substrate 110 and including a first redistribution pattern 121, and a first pad 130 disposed on an outermost side of the first redistribution layer 120, a second semiconductor chip 200 including a second semiconductor substrate 210, a second redistribution layer 220 disposed on the second semiconductor substrate 210 and including a second redistribution pattern 221, and a second pad 230 disposed on an outermost side of the second redistribution layer 220, the second semiconductor chip 200 being stacked on the first semiconductor chip 100 such that the first pad 130 and the second pad 230 are bonded to each other with the first redistribution layer 120 and the second redistribution layer 220 facing each other, and the second semiconductor chip 200 having an area smaller than an area of the first semiconductor chip 100 on a plane, a first metal wire 410 disposed on the first semiconductor chip 100, a second metal wire 420 disposed on the second semiconductor chip 200, a second through-via 442 passing through the second semiconductor substrate 210 and protruding from the second semiconductor substrate 210, and a molding member 480 disposed on the first semiconductor chip 100 and covering at least a portion of each of the second semiconductor chip 200, the first metal wire 410, the second metal wire 420, and the second through-via 442.

The first semiconductor chip 100 may be a substrate that is formed based on a wafer. The first semiconductor substrate 110 may include a semiconductor material, such as silicon (Si), germanium (Ge), or gallium arsenide (GaAs). Various circuits may be formed in the first semiconductor substrate 110. The first redistribution layer 120 may include the first redistribution pattern 121. The first redistribution pattern 121 may include a conductive material, such as copper (Cu), aluminum (Al), or tungsten (W). The first redistribution pattern 121 may include a trace pattern, a via pattern, and the like. The trace pattern may include a pad pattern connected to the via pattern. The first redistribution pattern 121 may be surrounded by an anti-diffusion layer. The anti-diffusion layer may include titanium (Ti), titanium nitride (TiN), tantalum (Ta), tantalum nitride (TaN), ruthenium (Ru), cobalt (Co), manganese (Mn), tungsten nitride (WN), nickel (Ni), and/or nickel boron (NiB). The first redistribution pattern 121 may be formed on an interlayer insulating layer of the first redistribution layer 120. The interlayer insulating layer may include oxide, nitride, or oxynitride, and may include, for example, silicon oxide, silicon nitride, and/or silicon oxynitride. A plurality of first pads 130 may be disposed. The first pad 130 may be electrically connected to the first redistribution pattern 121. The first pad 130 may include a conductive material, such as copper (Cu), aluminum (Al), or tungsten (W). The first semiconductor chip 100 may further include a first passivation layer 140 disposed on the first redistribution layer 120 and covering at least a portion of the first pad 130. The first passivation layer 140 may include oxide, nitride, or oxynitride, and may include, for example, silicon oxide, silicon nitride, and/or silicon oxynitride. The first passivation layer 140 may include an organic insulating material.

The second semiconductor chip 200 may include an integrated circuit (IC) die in which hundreds to millions of devices are integrated into one chip. The IC die may be, for example, a central processing unit (CPU), a graphics processing unit (GPU), a field programmable gate array (FPGA), an application processor (AP), an application-specific IC (ASIC), a volatile memory (e.g., DRAM), a non-volatile memory (e.g., ROM), a flash memory, a high bandwidth memory (HBM), and the like. The second semiconductor substrate 210 may include a semiconductor material, such as silicon (Si), germanium (Ge), or gallium arsenide (GaAs). Various circuits may be formed in the second semiconductor substrate 210. The second redistribution layer 220 may include the second redistribution pattern 221. The second redistribution pattern 221 may include a conductive material, such as copper (Cu), aluminum (Al), or tungsten (W). The second redistribution pattern 221 may include a trace pattern, a via pattern, and the like. The trace pattern may include a pad pattern connected to the via pattern. The second redistribution pattern 221 may be surrounded by an anti-diffusion layer. The anti-diffusion layer may include titanium (Ti), titanium nitride (TiN), tantalum (Ta), tantalum nitride (TaN), ruthenium (Ru), cobalt (Co), manganese (Mn), tungsten nitride (WN), nickel (Ni), and/or nickel boron (NiB). The second redistribution pattern 221 may be formed in an interlayer insulating layer of the second redistribution layer 220. The interlayer insulating layer may include oxide, nitride, or oxynitride, and may include, for example, silicon oxide, silicon nitride, and/or silicon oxynitride. The second pad 230 may be provided in plural. The second pad 230 may be electrically connected to the second redistribution pattern 221. The second pad 230 may include a conductive material, such as copper (Cu), aluminum (Al), or tungsten (W). The second semiconductor chip 200 may further include a second passivation layer 240 disposed on the second redistribution layer 220 and disposed on or covering at least a portion of the second pad 230. The second passivation layer 240 may include oxide, nitride, or oxynitride, and may include, for example, silicon oxide, silicon nitride, and/or silicon oxynitride. The second passivation layer 240 may include an organic insulating material.

The second semiconductor chip 200 may be bonded to the first semiconductor chip 100 in a die-to-wafer form. For example, the first pad 130 and the second pad 230 may directly contact each other. The first passivation layer 140 and the second passivation layer 240 may also directly contact each other.

The first metal wire 410 may include a metal material, such as copper (Cu) or aluminum (Al). The first metal wire 410 may be bonded to the first semiconductor chip 100. For example, the first metal wire 410 may be bonded to the bonding pad 405 disposed on an upper surface of the first passivation layer 140. The first metal wire 410 may be disposed around the second semiconductor chip 200 on a plane. A plurality of first metal wires 410 may be disposed. Since the first metal wire 410 is pre-formed prior to CMP processing, problems, such as dishing and rounding occurring during the CMP processing of the molding member 480, may be prevented. In addition, a heat dissipation effect may be achieved through the first metal wire 410. The first metal wire 410 may include a first-first metal wire 411 and a first-second metal wire 412. At least a portion of the first-first metal wire 411 may be inclined in a direction toward the second metal wire 420 in a cross-section. The first-second metal wire 412 may be disposed substantially vertically in a cross-section. Each of the first-first metal wire 411 and the first-second metal wire 412 may be disposed in plural, and an upper surface thereof may be exposed from an upper surface of the molding member 480. The first-first metal wire 411 may be used as a reveal mark together with the second metal wire 420. For example, when a thickness of the molding member 480 is reduced, since the molding member 480 is transparent, it may be difficult to identify a height difference occurring as a result of CMP processing. However, as in example embodiments, when the first-first metal wire 411 and the second metal wire 420 are exposed as a pair from the upper surface of the molding member 480, the pair of first-first metal wires 411 and the second metal wire 420 may be used as a reveal mark. The first-second metal wire 412 may be used as a dummy wire for pattern density control or heat dissipation and/or an electrical connection structure for 3D connection. As shown in the example embodiment of FIG. 2, the first-first metal wires 411 and the first-second metal wires 412 may be disposed around the second semiconductor chip substrate 210 as viewed in a top plan view.

The second metal wire 420 may include a metal material, such as copper (Cu) or aluminum (Al). The second metal wire 420 may be bonded to the second semiconductor chip 200. For example, the second metal wire 420 may be bonded to an upper surface of the second semiconductor substrate 210. At least a portion of the second metal wire 420 may be inclined in a direction toward the first-first metal wire 411 in a cross-section. For example, as shown in the example embodiment of FIG. 1, the first-first metal wire 411 may be inclined to the right, towards the second metal wire 420, and the second metal wire 420 may be inclined to the left, towards the first-first metal wire 411. The second metal wire 420 may be provided in plural, and an upper surface of each of the plurality of second metal wires 420 may be exposed from the upper surface of the molding member 480. The second metal wire 420 may be used as a reveal mark together with the first-first metal wire 411. In addition, the second metal wire 420 may also be used as a dummy wire for heat dissipation.

The second through-via 442 may pass through the second semiconductor substrate 210. The second through-via 442 may include a conductive material, such as copper (Cu) or aluminum (Al). The second through-vias 442 may be disposed substantially vertically when viewed in a cross-section. The second through-via 442 may have a cylindrical shape or a polygonal column shape, although example embodiments are not limited thereto. The second through-via 442 may protrude from the second semiconductor substrate 210 so that an upper surface thereof may be exposed from the upper surface of the molding member 480. The second through-via 442 may be electrically connected to the second redistribution pattern 221 and may be used as a 3D electrical connection path. In addition, the second through-via 442 may provide a heat dissipation path. A pattern density of the second through-via 442 may be equal to or smaller than that of the first metal wire 410.

The molding member 480 may be formed by performing gap filling through flowable chemical vapor deposition (FCVD) or dispensing of a polymer solution. The molding member 480 may have a high transparency. For example, the molding member 480 may have transparency higher than the first semiconductor substrate 110 and the second semiconductor substrate 120. Accordingly, components on which the molding member 480 are disposed or which are covered by the molding member 480 may be visually identified when viewed in a top view. Transparency may be measured using a scanning microscope or optical microscope. Alternatively or additionally, transparency may be determined by transmittance and haze values. Transparency may also be determined through reflectance.

A third semiconductor chip may also be disposed on the second semiconductor chip 200. In this case, the second through-via 442 may not protrude from the second semiconductor substrate 210. Also, the second metal wire 420 may be bonded on the third semiconductor chip, instead of the second semiconductor chip 200. The third semiconductor chip may have a structure that is the same as or substantially similar to the structure of the second semiconductor chip 200 described above, and may be stacked such that pads are bonded to the second through-vias 442.

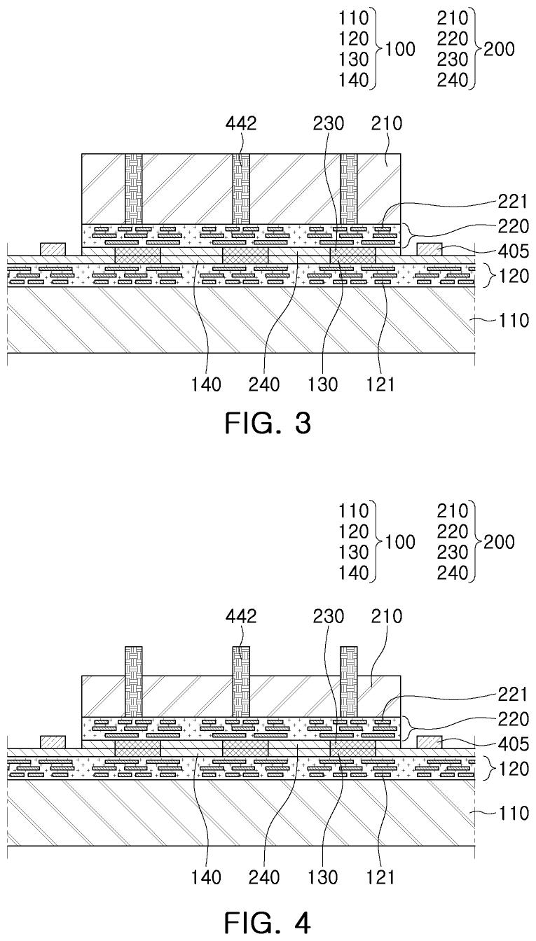

FIGS. 3 to 7 are cross-sectional views illustrating a sequential process of a method of manufacturing a semiconductor chip stack structure according to the example embodiments illustrated in FIG. 1.

Referring to FIG. 3, the second semiconductor chip 200 is stacked and bonded on the first semiconductor chip 100. For example, the first passivation layer 140 and the second passivation layer 240 may be bonded through a heat treatment, and then the first pad 130 and the second pad 230 may be bonded by a heat treatment at a higher temperature than the heat treatment at which the first passivation layer 140 and the second passivation layer 240 are bonded. Through this, an intermetallic bond may be formed.

Referring to FIG. 4, the second semiconductor substrate 210 may be etched so that the second through-via 442 protrudes from the second semiconductor substrate 210.

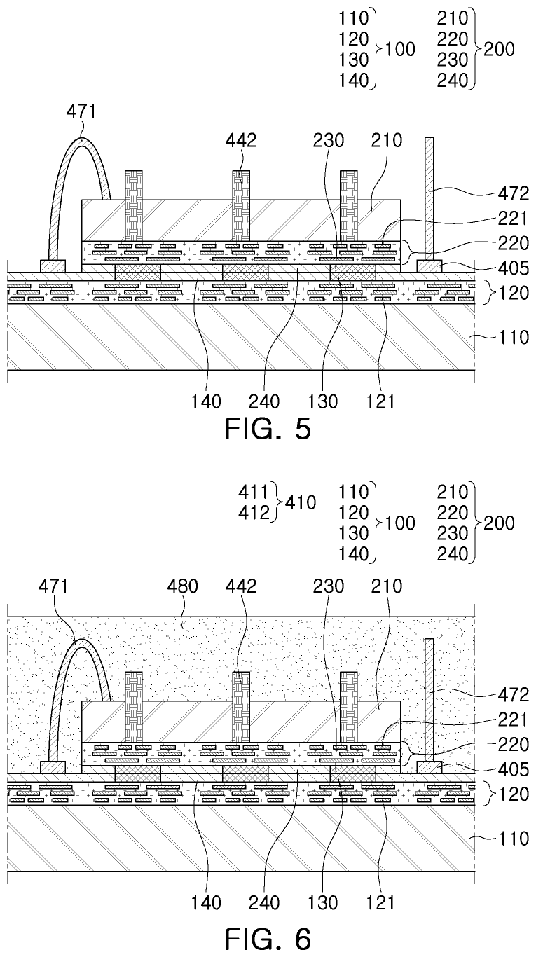

Referring to FIG. 5, a first bonding wire 471 and a second bonding wire 472 are formed. The first bonding wire 471 may be bent to connect the first semiconductor chip 100 and the second semiconductor chip 200. The second bonding wire 472 may be vertically disposed on the first semiconductor chip 100. The first bonding wire 471 and the second bonding wire 472 may be bonded to the bonding pad 405. The first bonding wire 471 may have a height greater than the sum of the heights of the second semiconductor chip 200 and an exposed portion of the second through-via 442.

Referring to FIG. 6, a space on the first semiconductor chip 100 may be filled using the molding member 480. For example, the molding member 480 may be disposed on or cover at least a portion of each of the second semiconductor chip 200, the first bonding wire 471 and the second bonding wire 472, and the second through-via 442.

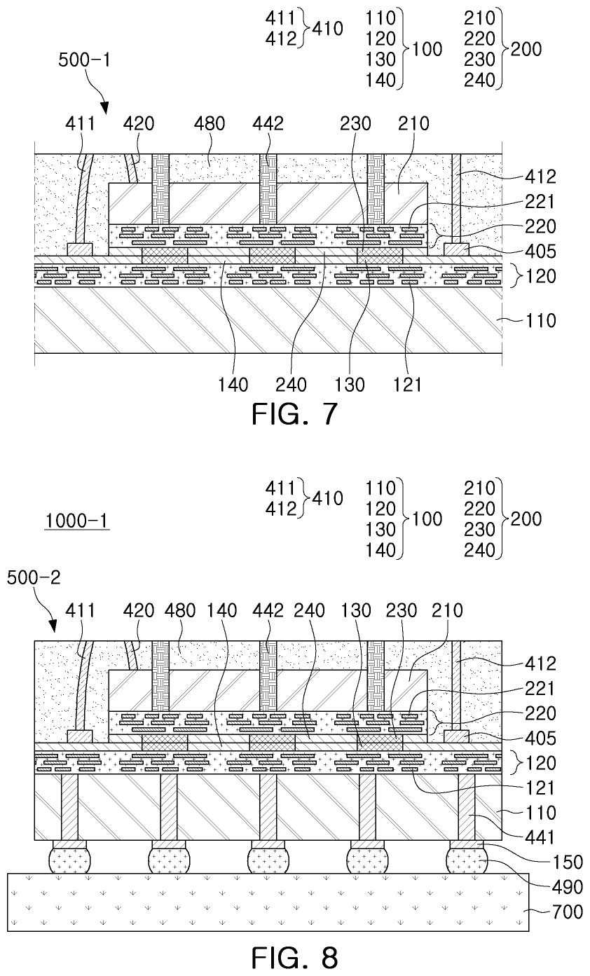

Referring to FIG. 7, a CMP process is performed. In this case, dishing and rounding may be prevented by the first bonding wire 471 and the second bonding wire 472. Upper portions of the first bonding wire 471 and the second bonding wire 472 may be cut by the CMP process to form the first metal wires 410 and the second metal wire 420. Also, an upper surface of the second through-via 442 may be exposed. The first metal wire 410 and the second metal wire 420 may be used as dummy wires for pattern density control or heat dissipation. The first-first metal wire 411 and the second metal wire 420 may be used as a reveal mark.

Through the sequential processes, the semiconductor chip stack structure 500-1 described above may be manufactured. Other features of the example embodiment may be substantially the same as those given to describe the semiconductor chip stack structure 500-1 above, and thus, redundant descriptions thereof will be omitted.

FIG. 8 is a schematic cross-sectional view of a semiconductor package according to example embodiments.

Referring to FIG. 8, a semiconductor package 1000-1 may include a printed circuit board (PCB) 700 and a semiconductor chip stack structure 500-2 disposed on the PCB 700.

The semiconductor chip stack structure 500-2 described above may further include a first through-via 441 passing through the first semiconductor substrate 110 and a fifth pad 150 disposed on a side opposite to the side on which the first redistribution layer 120 of the first semiconductor substrate 110 in the semiconductor chip stack structure 500-1 described above. The semiconductor chip stack structure 500-2 may be disposed on the PCB 700 such that the fifth pad 150 faces the PCB 700. The fifth pad 150 may be connected to the PCB 700 through a connection member 490.

The PCB 700 may be one or more of various types of substrates, such as a package substrate or an interposer substrate, and may have a multi-layered shape.

The first through-via 441 may pass through the first semiconductor substrate 110. The first through-via 441 may include a conductive material, such as copper (Cu) or aluminum (Al). The first through-vias 441 may be disposed substantially vertically in a cross-section. The first through-via 441 may have a cylindrical shape or a polygonal column shape, though example embodiments are not limited thereto. The first through-via 441 may be electrically connected to the first redistribution pattern 121 and the fifth pad 150 and may be used as a 3D electrical connection path.

The fifth pad 150 may be provided in plural. The fifth pad 150 may be electrically connected to the first redistribution pattern 121. The fifth pad 150 may include a conductive material, such as copper (Cu), aluminum (Al), or tungsten (W).

The connection member 490 may include a metal with a lower melting point than that of copper (Cu), for example, tin (Sn) or an alloy including tin (Sn). For example, the connection member 490 may include solder and may have a shape such as a land, a ball, or a pin shape. The connection members 490 may be provided in plural.

Other features of the example embodiment may be substantially the same as those given to describe the semiconductor chip stack structure 500-1 above, and thus, redundant descriptions thereof will be omitted.

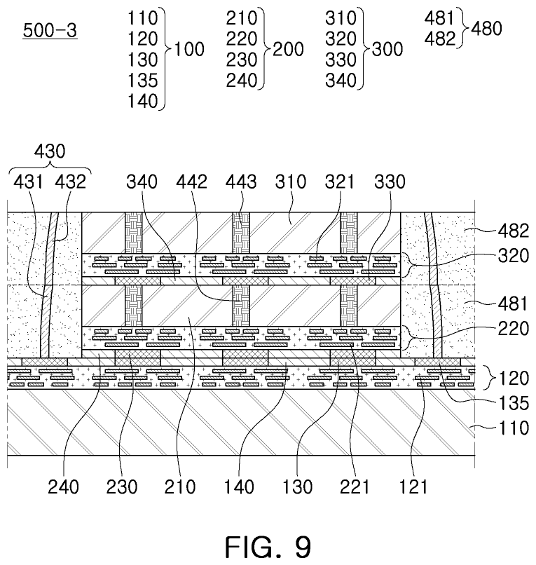

FIG. 9 is a schematic cross-sectional view of a semiconductor chip stack structure according to example embodiments.

Referring to FIG. 9, a semiconductor chip stack structure 500-3 may include the first semiconductor chip 100 including a first semiconductor substrate 110, the first redistribution layer 120 disposed on the first semiconductor substrate 110 and including the first redistribution pattern 121, and the first pad 130 disposed on an outermost side of the first redistribution layer 120, the second semiconductor chip 200 including a second semiconductor substrate 210, the second redistribution layer 220 disposed on the second semiconductor substrate 210 and including the second redistribution pattern 221, and the second pad 230 disposed on an outermost side of the second redistribution layer 220, the second semiconductor chip 200 being stacked on the first semiconductor chip 100 such that the first pad 130 and the second pad230 are bonded to each other with the first redistribution layer 120 and the second redistribution layer 220 facing each other, and the second semiconductor chip 200 having an area smaller than an area of the first semiconductor chip 100 on a plane, the second through-via 442 passing through the second semiconductor substrate 210, a third semiconductor chip 300 including a third semiconductor substrate 310, a third redistribution layer 320 disposed on the third semiconductor substrate 310 and including a third redistribution pattern 321, and a third pad 330 disposed on the outermost side of the third redistribution layer 320, the third semiconductor chip 300 being stacked on the second semiconductor chip 200 so that the third pad 330 is bonded to the second through-via 442, the third semiconductor chip 300 having an area smaller than that of the first semiconductor chip 100 on a plane, a through-via 443 passing through the semiconductor substrate 310, a third metal wire 430 disposed on the first semiconductor chip 100, and a molding member 480 disposed on the first semiconductor chip 100 and covering at least a portion of each of the second semiconductor chip 200 and the third semiconductor chip 300 and the third metal wire 430.

The third semiconductor chip 300 may include an IC die in which hundreds to millions of devices may be integrated into one chip. The IC die may be, for example, a central processing unit (CPU), a graphics processing unit (GPU), a field programmable gate array (FPGA), an application processor (AP), an application-specific IC (ASIC), a volatile memory (e.g., DRAM), a non-volatile memory (e.g., ROM), a flash memory, a high bandwidth memory (HBM), and the like. The third semiconductor substrate 310 may include a semiconductor material, such as silicon (Si), germanium (Ge), or gallium arsenide (GaAs). Various circuits may be formed in the third semiconductor substrate 310. The third redistribution layer 320 may include the third redistribution pattern 321. The third redistribution pattern 321 may include a conductive material, such as copper (Cu), aluminum (Al), or tungsten (W). The third redistribution pattern 321 may include a trace pattern, a via pattern, and the like. The trace pattern may include a pad pattern connected to the via pattern. The third redistribution pattern 321 may be surrounded by an anti-diffusion layer. The anti-diffusion layer may include titanium (Ti), titanium nitride (TiN), tantalum (Ta), tantalum nitride (TaN), ruthenium (Ru), cobalt (Co), manganese (Mn), tungsten nitride (WN), nickel (Ni), and/or nickel boron (NiB). The third redistribution pattern 321 may be formed in an interlayer insulating layer of the third redistribution layer 320. The interlayer insulating layer may include oxide, nitride, or oxynitride, and may include, for example, silicon oxide, silicon nitride, and/or silicon oxynitride. The third pad 330 may be provided in plural. The third pad 330 may be electrically connected to the third redistribution pattern 321. The third pad 330 may include a conductive material, such as copper (Cu), aluminum (Al), or tungsten (W). The third semiconductor chip 300 may further include a third passivation layer 340 disposed on the third redistribution layer 320 and covering at least a portion of the third pad 330. The third passivation layer 340 may include oxide, nitride, or oxynitride, and may include, for example, silicon oxide, silicon nitride, and/or silicon oxynitride. The third passivation layer 340 may include an organic insulating material.

The third semiconductor chip 300 may be directly bonded to the second semiconductor chip 200. For example, the third pad 330 may directly contact the second through-via 442. The third passivation layer 340 may directly contact the second semiconductor substrate 210.

The third metal wire 430 may include a metal material, such as copper (Cu) or aluminum (Al). The third metal wire 430 may be bonded to the first semiconductor chip 100. For example, the first semiconductor chip 100 may further include a fourth pad 135 disposed on the outermost side of the first redistribution layer 120 and disposed around the second semiconductor chip 200 and the third semiconductor chip 300 on a plane. The third metal wire 430 may be bonded to the fourth pad 135 and disposed around the second semiconductor chip 200 and the third semiconductor chip 300 on a plane. The third metal wires 430 may be provided in plural. Since the third metal wire 430 is formed in advance prior to CMP processing, problems, such as dishing and rounding occurring during the CMP processing of the molding member 480, may be prevented. In addition, a heat dissipation effect may be obtained through the third metal wire 430. The third metal wire 430 may include a third-first metal wire 431 and a third-second metal wire 432. The third-first metal wire 431 may be disposed on the side of the second semiconductor chip 200 in a cross-section. The third-second metal wire 432 may be disposed on the side of the third semiconductor chip 300 in a cross-section. The third metal wire 430 may have a form in which the third-first metal wire 431 and the third-second metal wires 432 are bonded to each other. The third metal wire 430 may be used as a dummy wire for pattern density control or heat dissipation, and/or an electrical connection structure for 3D connection.

Upper surfaces of the third semiconductor substrate 310, the third through-via 443, the third metal wire 430, and the molding member 480 may be substantially coplanar with each other.

The molding member 480 may include a plurality of layers. For example, the molding member 480 may include a first molding member 481 and a second molding member 482. The first molding member 481 and the second molding member 482 may each include the same material.

A fourth semiconductor chip may be further disposed on the third semiconductor chip 300 in the same shape as the third semiconductor chip 300. In this case, the third metal wire 430 may further include a third metal wire disposed on the side of the fourth semiconductor chip. In addition, a greater number of semiconductor chips may be stacked in such a stacked form.

Additional semiconductor chips may be further disposed on the third semiconductor chip 300 or on the uppermost semiconductor chip when a greater number of semiconductor chips are stacked in the same form. The additionally disposed semiconductor chip may be connected to the third metal wire 430 through bonding wire to have a 3D electrical connection path. Alternatively, the additionally disposed semiconductor chip may be mounted on an additional pad disposed on the third semiconductor chip 300 or the uppermost semiconductor chip when a greater number of semiconductor chips are stacked in the same form through a connection member to have a 3D electrical connection path.

Other features of the example embodiment may be substantially the same as those given to describe the semiconductor chip stack structure 500-1 above, and thus, redundant descriptions thereof will be omitted.

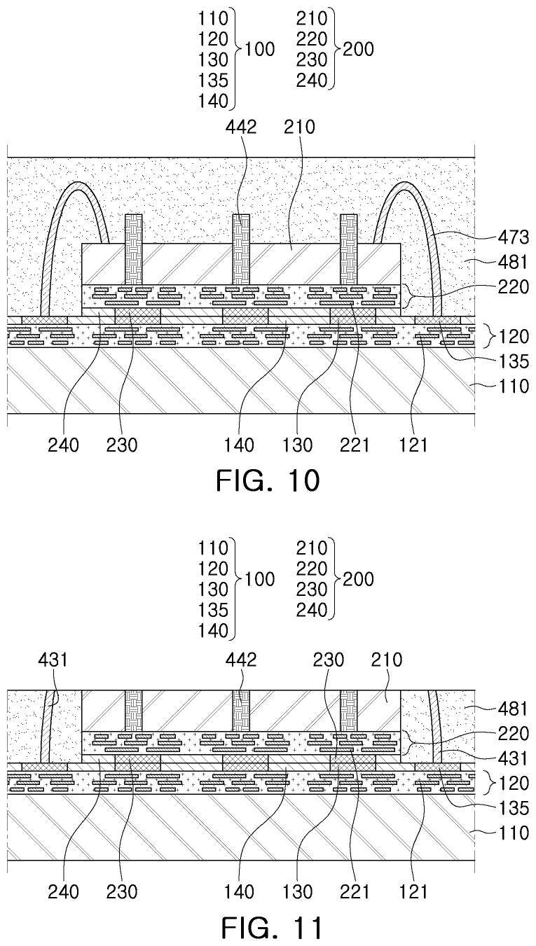

FIGS. 10 to 15 are cross-sectional views illustrating sequential processes of a method of manufacturing a semiconductor chip stack structure according to the example embodiment illustrated in FIG. 9.

Referring to FIG. 10, first, the second semiconductor chip 200 is stacked and bonded on the first semiconductor chip 100. For example, the first passivation layer 140 and the second passivation layer 240 may be bonded through a heat treatment, and then the first pad 130 and the second pad 230 may be bonded by a heat treatment at a higher temperature. Through this, an intermetallic bond may be formed. Next, the second semiconductor substrate 210 may be etched so that the second through-via 442 protrudes from the second semiconductor substrate 210. Next, third bonding wire 473 is performed. The third bonding wire 473 may be bent to connect the first semiconductor chips 100 and the second semiconductor chip 200. The third bonding wire 473 may be bonded to the fourth pad 135. The third bonding wire 473 may have a height greater than the sum of the heights of the second semiconductor chip 200 and an exposed portion of the second through-via 442. Next, a space on the first semiconductor chip 100 is filled by using the first molding member 481. For example, the first molding member 481 may cover at least a portion of each of the second semiconductor chip 200, the third bonding wire 473, and the second through-via 442.

Referring to FIG. 11, a CMP process is performed. At this time, dishing, rounding, etc. may be prevented by the third bonding wire 473. An upper portion of the third bonding wire 473 may be cut by the CMP process to form a third-first metal wire 431. Also, an upper surface of the second through-via 442 may be exposed.

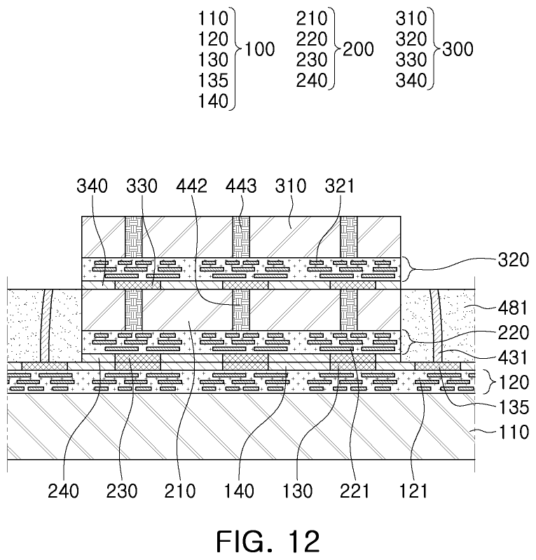

Referring to FIG. 12, a third semiconductor chip 300 is stacked and bonded on the second semiconductor chip 200. For example, the third passivation layer 340 and the second semiconductor substrate 210 may be bonded through a heat treatment, and then heat treated at a higher temperature to form the third pad 330 and the third through-via 443. Through this, an intermetallic bond may be formed. Next, the third semiconductor substrate 310 may be etched so that the third through-via 443 protrudes from the second semiconductor substrate 210.

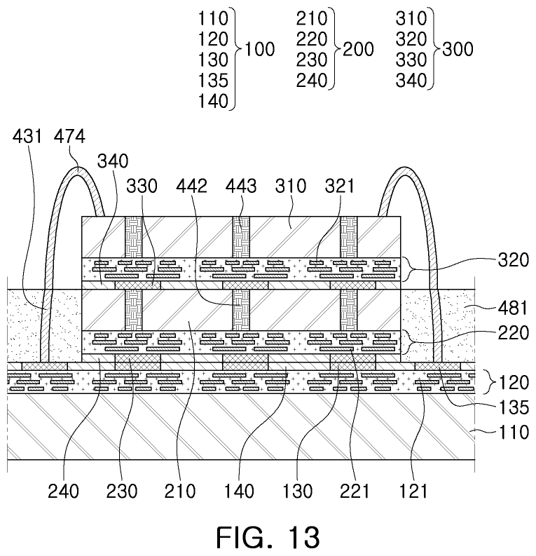

Referring to FIG. 13, a process involving a fourth bonding wire 474 is performed. The fourth bonding wire 474 may be bent to connect the third bonding wire 473 and the third semiconductor chip 300. The fourth bonding wire 474 may be bonded to the exposed upper surface of the third bonding wire 473. The fourth bonding wire 474 may have a height greater than the sum of the heights of the third semiconductor chip 300 and the exposed portion of the third through-via 443.

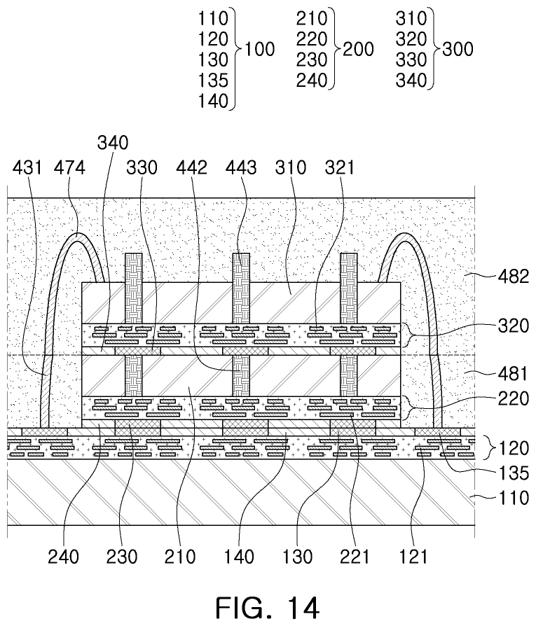

Referring to FIG. 14, a space on the first molding member 481 is filled using the second molding member 482. For example, the second molding member 482 may be disposed on or cover at least a portion of each of the third semiconductor chip 300, the fourth bonding wire 474, and the third through-via 443.

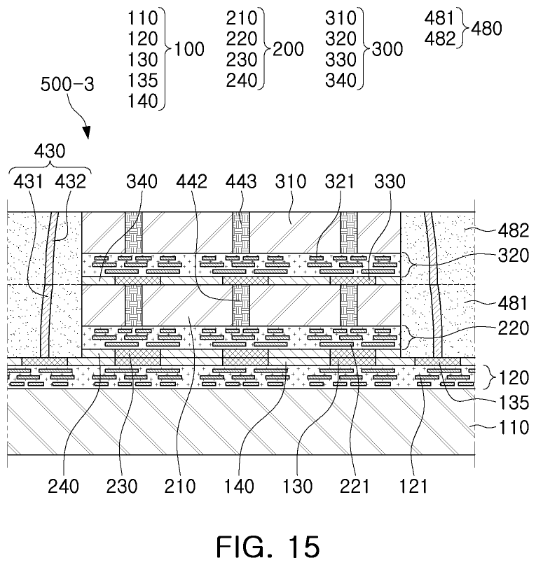

Referring to FIG. 15, a CMP process is performed. In this case, dishing and rounding may be prevented by the fourth bonding wire 474. An upper portion of the fourth bonding wire 474 may be cut by the CMP process to form the third-second metal wire 432. Also, an upper surface of the third through-via 443 may be exposed.

Through the sequential processes, the semiconductor chip stack structure 500-3 described above may be manufactured. Other descriptions are substantially the same as those give to describe the semiconductor chip stack structure 500-3 above, and thus, redundant descriptions thereof are omitted.

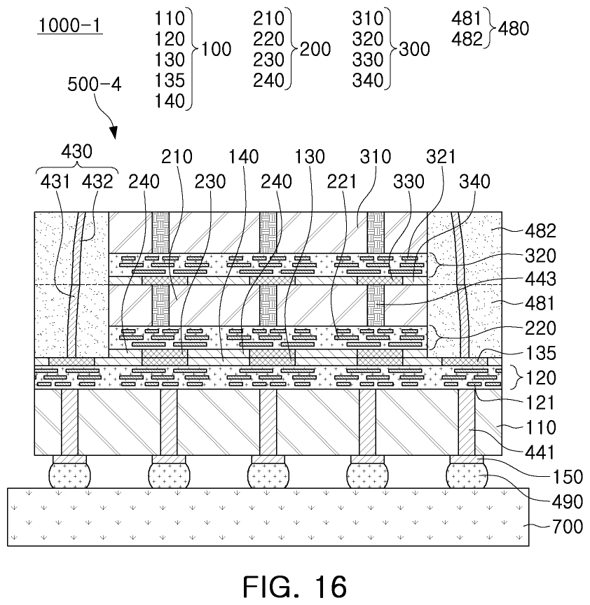

FIG. 16 is a schematic cross-sectional view of a semiconductor package according to example embodiments.

Referring to FIG. 16, a semiconductor package 1000-2 may include the PCB 700 and a semiconductor chip stack structure 500-4 disposed on the PCB 700.

The semiconductor chip stack structure 500-4 described above may further include a first through-via 441 passing through the first semiconductor substrate 110 and a fifth pad 150 disposed on a side opposite to the side on which the first redistribution layer 120 of the first semiconductor substrate 110 in the semiconductor chip stack structure 500-3 described above. The semiconductor chip stack structure 500-4 may be disposed on the PCB 700 such that the fifth pad 150 faces the PCB 700. The fifth pad 150 may be connected to the PCB 700 through a connection member 490.

The PCB 700 may be one or more of various types of substrates, such as a package substrate or an interposer substrate, and may have a multi-layered shape.

The first through-via 441 may pass through the first semiconductor substrate 110. The first through-via 441 may include a conductive material, such as copper (Cu) or aluminum (Al). The first through-vias 441 may be disposed substantially vertically in a cross-section. The first through-via 441 may have a cylindrical shape, but may also have a polygonal column shape. The first through-via 441 may be electrically connected to the first redistribution pattern 121, the fourth pad 135 and/or the fifth pad 150 and may be used as a 3D electrical connection path.

The fifth pad 150 may be provided in plural. The fifth pad 150 may be electrically connected to the first redistribution pattern 121. The fifth pad 150 may include a conductive material, such as copper (Cu), aluminum (Al), or tungsten (W).

The connection member 490 may include a metal with a lower melting point than that of copper (Cu), for example, tin (Sn) or an alloy including tin (Sn). For example, the connection member 490 may include solder and may have a shape such as a land, a ball, or a pin shape. The connection members 490 may be provided in plural.

Other features of the example embodiment may be substantially the same as those given to describe the semiconductor chip stack structure 500-1 above, and thus, redundant descriptions thereof will be omitted.

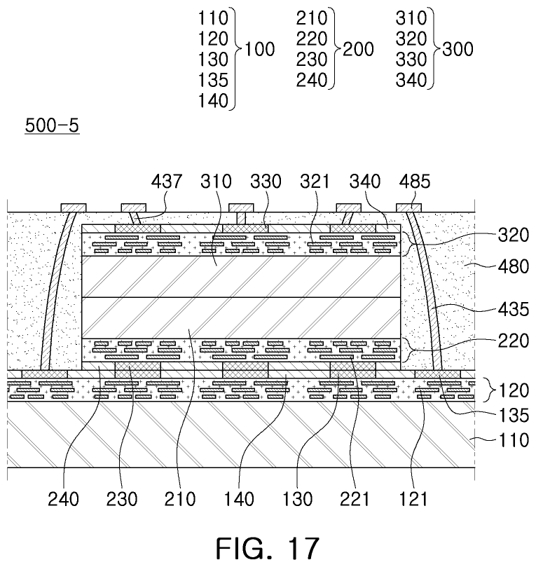

FIG. 17 is a schematic cross-sectional view of a semiconductor chip stack structure according to example embodiments.

Referring to FIG. 17, the semiconductor chip stack structure 500-5 may include the first semiconductor chip 100 including a first semiconductor substrate 110, the first redistribution layer 120 disposed on the first semiconductor substrate 110 and including the first redistribution pattern 121, and the first pad 130 disposed on an outermost side of the first redistribution layer 120, the second semiconductor chip 200 including a second semiconductor substrate 210, the second redistribution layer 220 disposed on the second semiconductor substrate 210 and including the second redistribution pattern 221, and the second pad 230 disposed on an outermost side of the second redistribution layer 220, the second semiconductor chip 200 being stacked on the first semiconductor chip 100 such that the first pad 130 and the second pad 230 are bonded to each other with the first redistribution layer 120 and the second redistribution layer 220 facing each other, and the second semiconductor chip 200 having an area smaller than an area of the first semiconductor chip 100 on a plane, a third semiconductor chip 300 including a third semiconductor substrate 310, a third redistribution layer 320 disposed on the third semiconductor substrate 310 and including a third redistribution pattern 321, and a third pad 330 disposed on the outermost side of the third redistribution layer 320, the third semiconductor chip 300 being stacked on the second semiconductor chip 200 so that the second semiconductor substrate 210 and the third semiconductor substrate 310 are bonded to each other, the third semiconductor chip 300 having an area smaller than that of the first semiconductor chip 100 on a plane, a fourth metal wire 435 disposed on the first semiconductor chip 100, a fifth metal wire 437 disposed on the third semiconductor chip 300, and the molding member 480 disposed on the first semiconductor chip 100 and covering at least a portion of each of the second semiconductor chip 200 and the third semiconductor chip 300 and the fourth metal wire 435 and the fifth metal wire 437.

The third semiconductor chip 300 may include an IC die in which hundreds to millions of devices are integrated into one chip. The IC die may be, for example, a central processing unit (CPU), a graphics processing unit (GPU), a field programmable gate array (FPGA), an application processor (AP), an application-specific IC (ASIC), a volatile memory (e.g., DRAM), a non-volatile memory (e.g., ROM), a flash memory, a high bandwidth memory (HBM), and the like. The third semiconductor substrate 310 may include a semiconductor material, such as silicon (Si), germanium (Ge), or gallium arsenide (GaAs). Various circuits may be formed in the third semiconductor substrate 310. The third redistribution layer 320 may include the third redistribution pattern 321. The third redistribution pattern 321 may include a conductive material, such as copper (Cu), aluminum (Al), or tungsten (W). The third redistribution pattern 321 may include a trace pattern, a via pattern, and the like. The trace pattern may include a pad pattern connected to the via pattern. The third redistribution pattern 321 may be surrounded by an anti-diffusion layer. The anti-diffusion layer may include titanium (Ti), titanium nitride (TiN), tantalum (Ta), tantalum nitride (TaN), ruthenium (Ru), cobalt (Co), manganese (Mn), tungsten nitride (WN), nickel (Ni), and/or nickel boron (NiB). The third redistribution pattern 321 may be formed in an interlayer insulating layer of the third redistribution layer 320. The interlayer insulating layer may include oxide, nitride, or oxynitride, and may include, for example, silicon oxide, silicon nitride, and/or silicon oxynitride. The third pad 330 may be provided in plural. The third pad 330 may be electrically connected to the third redistribution pattern 321. The third pad 330 may include a conductive material, such as copper (Cu), aluminum (Al), or tungsten (W). The third semiconductor chip 200 may further include a third passivation layer 340 disposed on the third redistribution layer 320 and covering at least a portion of the third pad 330. The third passivation layer 340 may include oxide, nitride, or oxynitride, and may include, for example, silicon oxide, silicon nitride, and/or silicon oxynitride. The third passivation layer 340 may include an organic insulating material.

The third semiconductor chip 300 may be directly bonded to the second semiconductor chip 200. For example, the second semiconductor substrate 210 and the third semiconductor substrate and 310 may directly contact each other. However, example embodiments are not limited thereto, and an adhesive film or the like may be used.

The fourth metal wire 435 may include a metal material, such as copper (Cu) or aluminum (Al). The fourth metal wire 435 may be bonded to the first semiconductor chip 100. For example, the first semiconductor chip 100 may further include a fourth pad 135 disposed on an outermost side of the first redistribution layer 120 and disposed around the second semiconductor chip 200 and the third semiconductor chip 300 on a plane. The fourth metal wire 435 may be bonded to the fourth pad 135 and disposed around the second semiconductor chip 200 and the third semiconductor chip 300 on a plane. The fourth metal wire 435 may be provided in plural. Since the fourth metal wire 435 is formed in advance prior to CMP processing, problems, such as dishing and rounding occurring during the CMP processing of the molding member 480, may be prevented. In addition, a heat dissipation effect may be obtained through the fourth metal wire 435. At least a portion of the fourth metal wire 435 may be inclined in a direction toward the fifth metal wire 437 in a cross-section. The fourth metal wire 435 may be provided in plural, and an upper surface of each of the plurality of fourth metal wires 435 may be exposed from the upper surface of the molding member 480. The fourth metal wire 435 may be used as a structure for pattern density control and/or an electrical connection structure for 3D connection.

The fifth metal wire 437 may include a metal material, such as copper (Cu) or aluminum (Al). The fifth metal wire 437 may be bonded to the third semiconductor chip 300. For example, the fifth metal wire 437 may be bonded to the third pad 330. At least a portion of the fifth metal wire 437 may be inclined in a direction toward the fourth metal wire 435 in a cross-section. At least another portion thereof may be disposed substantially vertically in a cross-section. The fifth metal wire 437 may be provided in plural, and an upper surface of each of the plurality of fifth metal wires 437 may be exposed from the upper surface of the molding member 480. The fifth metal wire 437 may be used as an electrical connection structure for 3D connection.

A sixth pad 485 bonded to an upper surface of each of the fourth metal wires 435 and the fifth metal wire 437 may be disposed on the molding member 480. The sixth pad 485 may include a conductive material, such as copper (Cu), aluminum (Al), or tungsten (W). The sixth pad 485 may be provided in plural.

An additional semiconductor chip may be disposed between the second semiconductor chip 200 and the third semiconductor chip 300, and in this case, a 3D electrical connection path may be provided by additionally forming a through-via or the like.

Other descriptions are substantially the same as those given to describe the semiconductor chip stack structure 500-1 above, and thus, redundant descriptions thereof will be omitted.

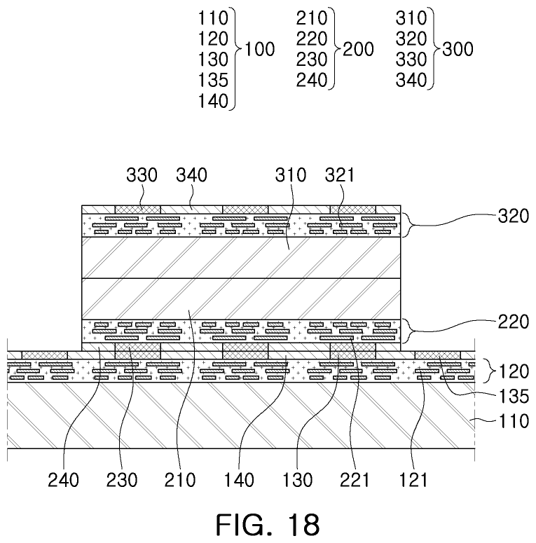

FIGS. 18 to 22 are cross-sectional views illustrating sequential processes of a method of manufacturing a semiconductor chip stack structure according to the example embodiments illustrated in FIG. 17.

Referring to FIG. 18, the second semiconductor chip 200 is stacked and bonded on the first semiconductor chip 100. For example, the first passivation layer 140 and the second passivation layer 240 may be bonded through a heat treatment, and then the first pad 130 and the second pad 230 may be bonded by a heat treatment at a higher temperature. Through this, an intermetallic bond may be formed. In addition, the third semiconductor chip 300 is stacked and bonded on the second semiconductor chip 200. For example, the second semiconductor substrate 210 and the third semiconductor substrate 310 may be bonded through a heat treatment. Alternatively, the second semiconductor substrate 210 and the third semiconductor substrate 310 may be attached using a separate adhesive film.

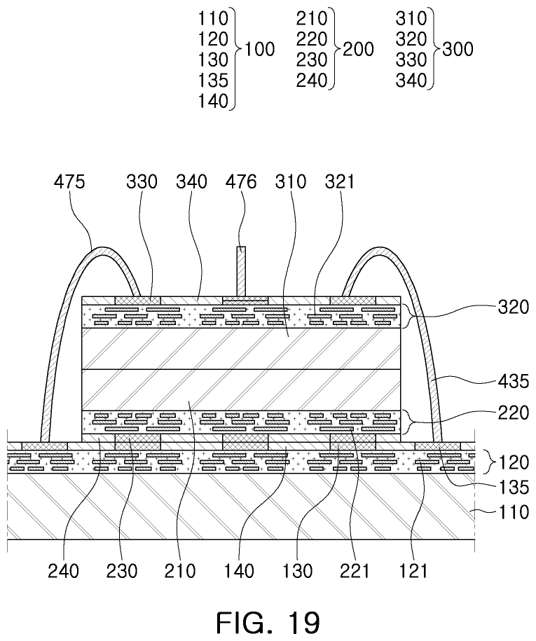

Referring to FIG. 19, fifth bonding wire 475 and the sixth bonding wire 476 are performed. The fifth bonding wire 475 may be bent to connect the first semiconductor chip 100 and the third semiconductor chips 300. The sixth bonding wire 476 may be vertically disposed on the third semiconductor chip 300. The fifth bonding wire 475 may be bonded to the third pad 330 and the fourth pad 135. The sixth bonding wire 476 may be bonded to the third pad 330. The fifth bonding wire 475 may have a height greater than the sum of the heights of the second semiconductor chip 200 and the third semiconductor chip 300.

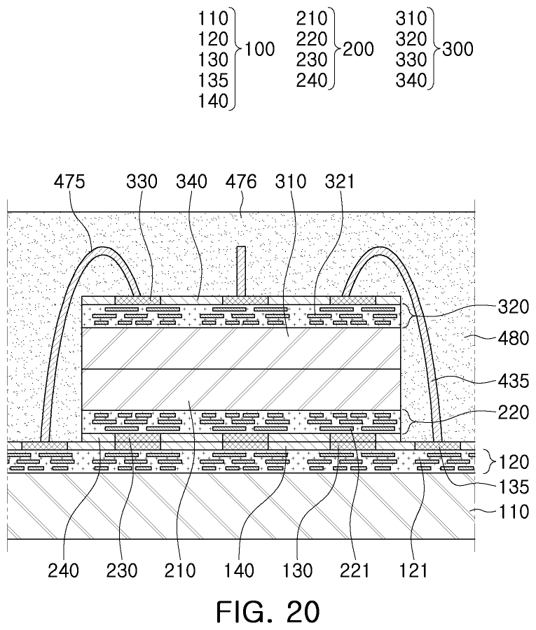

Referring to FIG. 20, a space on the first semiconductor chip 100 is filled using the molding member 480. For example, the molding member 480 may be disposed on or cover at least a portion of each of the second semiconductor chip 200 and the third semiconductor chip 300 and the fifth bonding wire 475 and the sixth bonding wire 476.

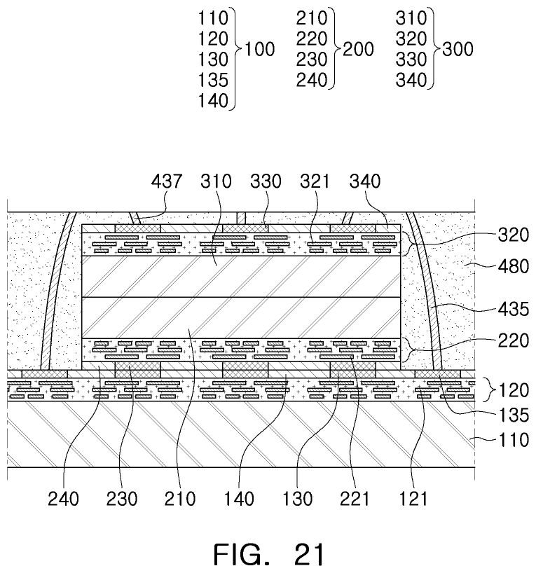

Referring to FIG. 21, a CMP process is performed. In this case, dishing and rounding may be prevented by the fifth bonding wire 475 and the sixth bonding wire 476. Upper portions of the fifth bonding wire 475 and the sixth bonding wire 476 may be cut by the CMP process to form the fourth metal wire 435 and the fifth metal wire 437. The fourth metal wire 435 and the fifth metal wire 437 may be used as a structure for a 3D electrical connection.

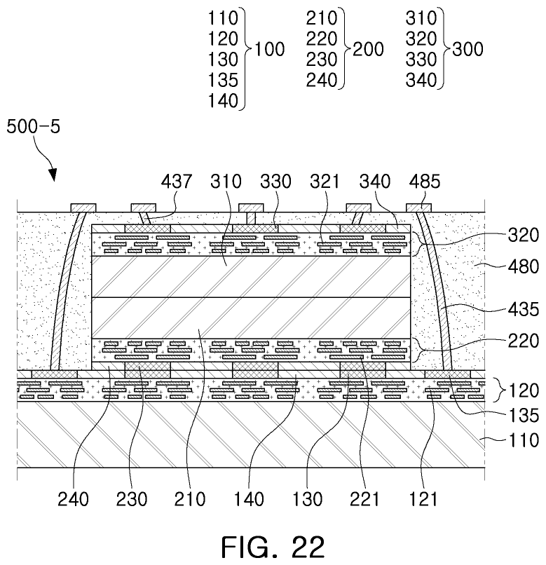

Referring to FIG. 22, a sixth pad 485 is formed on a molding member 480. The sixth pad 485 may be bonded to an upper surface of each of the fourth metal wire 435 and the fifth metal wire 437.

Through the sequential processes, the semiconductor chip stack structure 500-5 described above may be manufactured. Other descriptions are substantially the same as those given to describe the semiconductor chip stack structure 500-5, and thus, redundant descriptions thereof are omitted.

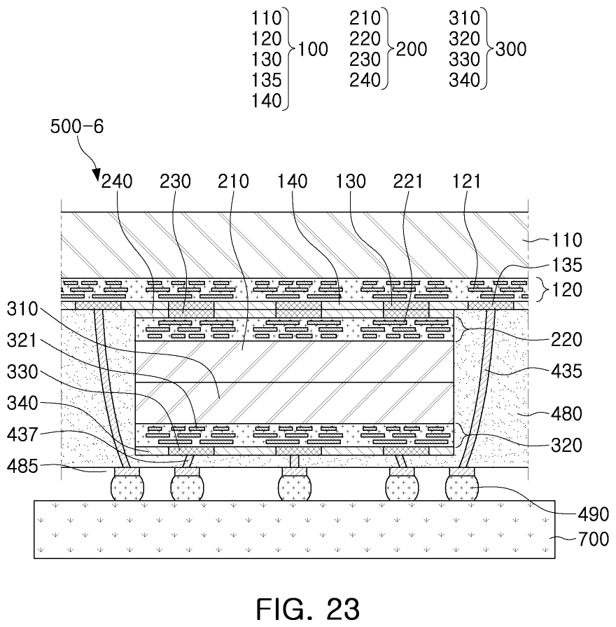

FIG. 23 is a schematic cross-sectional view of a semiconductor package according to example embodiments.

Referring to FIG. 23, a semiconductor package 1000-3 may include the PCB 700 and a semiconductor chip stack structure 500-6 disposed on the PCB 700.

The semiconductor chip stack structure 500-6 may have substantially the same structure as that of the semiconductor chip stack structure 500-5 described above, but may have a vertically inverted shape for mounting on the PCB 700. The semiconductor chip stack structure 500-6 may be disposed on the PCB 700 such that the sixth pad 485 faces the PCB 700. The sixth pad 485 may be connected to the PCB 700 through the connection member 490.

The PCB 700 may be various types of substrates, such as a package substrate and an interposer substrate, and may have a multi-layered shape.

The connection member 490 may include a metal with a lower melting point than copper (Cu), for example, tin (Sn) or an alloy including tin (Sn). For example, the connection member 490 may include solder and may have a shape, such as a land, a ball, or a pin. The connection members 490 may be provided in plural.

Other descriptions are substantially the same as those given to describe the semiconductor chip stack structure 500-5 above, and thus, redundant descriptions thereof are omitted.

According to example embodiments, in the semiconductor chip stack structure and a semiconductor package including the same according to example embodiments, in a die-to-wafer bonded stack structure, by forming a metal wire around a second semiconductor chip on a first semiconductor chip and then filling it with a molding member, the problems, such as dishing, rounding, or the like, in a CMP process may be solved, and in addition, a metal wire exposed after the CMP process may be utilized as a reveal mark and/or used as a structure for a 3D electrical connection.

While aspects of example embodiments have been particularly shown and described, it will be understood that various changes in form and details may be made therein without departing from the spirit and scope of the following claims.

What is claimed is:

1. A semiconductor chip stack structure comprising:
a first semiconductor chip comprising a first semiconductor substrate, a first redistribution layer on the first semiconductor substrate and comprising a first redistribution pattern, and a first pad on an outermost side of the first redistribution layer;
a second semiconductor chip comprising a second semiconductor substrate, a second redistribution layer on the second semiconductor substrate and comprising a second redistribution pattern, and a second pad on an outermost side of the second redistribution layer, the second semiconductor chip being stacked on the first semiconductor chip such that the first pad and the second pad are bonded to each other with the first redistribution layer and the second redistribution layer facing each other, and an area of the second semiconductor chip being smaller than an area of the first semiconductor chip;
a first metal wire on the first semiconductor chip;
a second metal wire on the second semiconductor chip; and
a molding member on the first semiconductor chip and at least a portion of each of the second semiconductor chip, the first metal wire, and the second metal wire,
wherein an upper surface of each of the first metal wire and the second metal wire is exposed from an upper surface of the molding member.

2. The semiconductor chip stack structure of claim 1, wherein:
the first metal wire comprises a first-first metal wire at least partially inclined in a direction toward the second metal wire, and
the second metal wire is at least partially inclined in a direction toward the first-first metal wire.

3. The semiconductor chip stack structure of claim 2, wherein:
the first metal wire further comprises a first-second metal wire extending substantially vertically, and
the second metal wire is closer to the first-first metal wire than the first-second metal wire.

4. The semiconductor chip stack structure of claim 1, wherein:
the first semiconductor chip further comprises a first passivation layer disposed on the first redistribution layer and at least a portion of the first pad,
the second semiconductor chip further comprises a second passivation layer on the second redistribution layer and at least a portion of the second pad, and
the first pad and the second pad are in direct contact with each other, and the first passivation layer and the second passivation layer are in direct contact with each other.

5. The semiconductor chip stack structure of claim 1, further comprising:
a through-via passing through the second semiconductor substrate and protruding from the second semiconductor substrate,
wherein the molding member is on at least a portion of the through-via, and an upper surface of the through-via is exposed from an upper surface of the molding member.

6. The semiconductor chip stack structure of claim 1, wherein a transparency of the molding member is higher than a transparency of the first semiconductor substrate and a transparency of the second semiconductor substrate.

7. A semiconductor chip stack structure comprising:
a first semiconductor chip comprising a first semiconductor substrate, a first redistribution layer on the first semiconductor substrate and comprising a first redistribution pattern, and a first pad on an outermost side of the first redistribution layer;
a second semiconductor chip comprising a second semiconductor substrate, a second redistribution layer on the second semiconductor substrate and comprising a second redistribution pattern, and a second pad on an outermost side of the second redistribution layer, the second semiconductor chip being stacked on the first semiconductor chip such that the first pad is bonded to the second pad and the first redistribution layer faces the second redistribution layer, and an area of the second semiconductor chip being smaller than an area of the first semiconductor chip;
a first metal wire on the first semiconductor chip; and
a molding member on the first semiconductor chip and at least a portion of each of the second semiconductor chip and the first metal wire.

8. The semiconductor chip stack structure of claim 7, further comprising:
a second metal wire on the second semiconductor chip,
wherein the molding member is on at least a portion of the second metal wire,
wherein an upper surface of each of the first metal wire and the second metal wire is exposed from an upper surface of the molding member, and
wherein at least a portion of each of the first metal wire and the second metal wire is inclined in a direction toward each other.

9. The semiconductor chip stack structure of claim 8, further comprising:
a through-via passing through the second semiconductor substrate and protruding from the second semiconductor substrate,
wherein the molding member is on at least a portion of the through-via, and
an upper surface of the through-via is exposed from the upper surface of the molding member.

10. The semiconductor chip stack structure of claim 7, further comprising:
a first through-via passing through the second semiconductor substrate;
a third semiconductor chip comprising a third semiconductor substrate, a third redistribution layer on the third semiconductor substrate and comprising a third redistribution pattern, and a third pad on an outermost side of the third redistribution layer, the third semiconductor chip stacked on the second semiconductor chip such that the third pad is bonded to the first through-via, and an area of the third semiconductor chip being smaller than an area of the first semiconductor chip; and
a second through-via passing through the third semiconductor substrate,
wherein the molding member is on at least a portion of the third semiconductor chip.

11. The semiconductor chip stack structure of claim 10, wherein the first metal wire comprises a first-first metal wire on a side portion of the second semiconductor chip and a first-second metal wire on a side portion of the third semiconductor chip, and
wherein the first-first metal wire is bonded to the first-second metal wire.

12. The semiconductor chip stack structure of claim 10, wherein:
the first semiconductor chip further comprises a fourth pad on an outermost side of the first redistribution layer and around the second semiconductor chip and the third semiconductor chip, and
the first metal wire is bonded to the fourth pad.

13. The semiconductor chip stack structure of claim 10, wherein an upper surface of the third semiconductor chip, an upper surface of the second through-via, an upper surface of the first metal wire, and an upper surface of the molding member are substantially coplanar.

14. The semiconductor chip stack structure of claim 7, further comprising:
a third semiconductor chip comprising a third semiconductor substrate, a third redistribution layer on the third semiconductor substrate and comprising a third redistribution pattern, and a third pad on an outermost side of the third redistribution layer, the third semiconductor chip stacked on the second semiconductor chip such that the second semiconductor substrate and the third semiconductor substrate are bonded to each other, an area of the third semiconductor chip being smaller than an area of the first semiconductor chip; and
a second metal wire on the third semiconductor chip,
wherein:
the first semiconductor chip further comprises a fourth pad disposed on an outermost side of the first redistribution layer and around the second semiconductor chip and the third semiconductor chip,
the first metal wire is bonded to the fourth pad,
the second metal wire is bonded to the third pad,
the molding member is on at least a portion of each of the third semiconductor chip and the second metal wire, and
an upper surface of each of the first metal wire and the second metal wire are exposed from an upper surface of the molding member.

15. The semiconductor chip stack structure of claim 14, wherein a fifth pad bonded to an upper surface of each of the first metal wire and the second metal wire is on the molding member.

16. The semiconductor chip stack structure of claim 14, wherein at least a portion of each of the first metal wire and the second metal wire is inclined in a direction toward each other.

17. A semiconductor package comprising:
a printed circuit board (PCB); and
a semiconductor chip stack structure on the PCB,
wherein the semiconductor chip stack structure comprises:
a first semiconductor chip comprising a first semiconductor substrate, a first redistribution layer disposed on the first semiconductor substrate and comprising a first redistribution pattern, and a first pad on an outermost side of the first redistribution layer;
a second semiconductor chip including a second semiconductor substrate, a second redistribution layer on the second semiconductor substrate and comprising a second redistribution pattern, and a second pad on an outermost side of the second redistribution layer, the second semiconductor chip stacked on the first semiconductor chip such that the first pad is bonded to the second pad with the first redistribution layer facing the second redistribution layer, and an area of the second semiconductor chip being smaller than an area of the first semiconductor chip;
a first metal wire on the first semiconductor chip; and
a molding member on the first semiconductor chip and at least a portion of each of the second semiconductor chip and the first metal wire.

18. The semiconductor package of claim 17, wherein the semiconductor chip stack structure further comprises:
a first through-via passing through the first semiconductor substrate;
a second metal wire on the second semiconductor chip; and
a second through-via passing through the second semiconductor substrate, wherein the molding member is on at least a portion of the second metal wire,
wherein an upper surface of each of the first metal wire and the second metal wire is exposed from an upper surface of the molding member,
wherein at least a portion of each of the first metal wire and the second metal wire is inclined in a direction toward each other,
wherein a third pad is further disposed on a side of the first semiconductor substrate opposite to a side on which the first redistribution layer is disposed,
wherein the semiconductor chip stack structure is disposed on the PCB so that the third pad faces the PCB, and
wherein the third pad is connected to the PCB through a connection member.

19. The semiconductor package of claim 17, wherein the semiconductor chip stack structure further comprises:
a first through-via passing through the first semiconductor substrate;
a second through-via passing through the second semiconductor substrate;
a third semiconductor chip comprising a third semiconductor substrate, a third redistribution layer on the third semiconductor substrate and comprising a third redistribution pattern, and a third pad on an outermost side of the third redistribution layer, the third semiconductor chip stacked on the second semiconductor chip such that the third pad is bonded to the second through-via, the third semiconductor chip having an area smaller than an area of the first semiconductor chip; and
a third through-via passing through the third semiconductor substrate,
wherein:
the molding member is on at least a portion of the third semiconductor chip,
the first semiconductor chip further comprises a fourth pad on an outermost side of the first redistribution layer and around the second semiconductor chip and the third semiconductor chip,
the first metal wire is bonded to the fourth pad,
the first metal wire comprises a first-first metal wire on a side portion of the second semiconductor chip and a first-second metal wire on a side portion of the third semiconductor chip, and the first-first metal wire is bonded to the first-second metal wire,
a fifth pad is disposed on a side of the first semiconductor substrate opposite to a side on which the first redistribution layer is disposed,
the semiconductor chip stack structure is on the PCB so that the fifth pad faces the PCB, and
the fifth pad is connected to the PCB through a connection member.

20. The semiconductor package of claim 17, wherein the semiconductor chip stack structure further comprises:
a third semiconductor chip comprising a third semiconductor substrate, a third redistribution layer on the third semiconductor substrate and comprising a third redistribution pattern, and a third pad on an outermost side of the third redistribution layer, the third semiconductor chip stacked on the second semiconductor chip such that the second semiconductor substrate is bonded to the third semiconductor substrate, and an area of the third semiconductor chip being smaller than an area of the first semiconductor chip; and
a second metal wire on the third semiconductor chip,
wherein:
the first semiconductor chip further comprises a fourth pad on an outermost side of the first redistribution layer and around the second semiconductor chip and the third semiconductor chip,
the first metal wire is bonded to the fourth pad,
the second metal wire is bonded to the third pad,
the molding member is on at least a portion of each of the third semiconductor chip and the second metal wire,
an upper surface of each of the first metal wire and the second metal wire is exposed from an upper surface of the molding member,
a fifth pad bonded to an upper surface of each of the first metal wire and the second metal wire is on the molding member,
the semiconductor chip stack structure is on the PCB so that the fifth pad faces the PCB, and
the fifth pad is connected to the PCB through a connection member.
